(19) United States
(12) Patent Application Publication
(10) Pub. No.: US 2024/0154030 A1
(43) Pub. Date: May 9, 2024

(54) SEMICONDUCTOR STRUCTURES AND MANUFACTURING METHODS THEREFOR

(71) Applicant: Enkris Semiconductor, Inc., Suzhou (CN)

(72) Inventor: KAI CHENG, Suzhou (CN)

(73) Assignee: Enkris Semiconductor, Inc., Suzhou (CN)

(21) Appl. No.: 18/495,110

(22) Filed: Oct. 26, 2023

(30) Foreign Application Priority Data
Nov. 3, 2022 (CN) 202211370296.7

(51) Int. Cl. H01L 29/778; H01L 29/06; H01L 29/423; H01L 29/775; H01L 29/786

(52) U.S. Cl. CPC H01L 29/7786; H01L 29/0673; H01L 29/42392; H01L 29/775; H01L 29/78696

(57) ABSTRACT

The present disclosure provides a semiconductor structure, including: a substrate structure; an epitaxial structure on the substrate structure, where the epitaxial structure includes at least one heterojunction structure sequentially stacked in a direction away from the substrate structure; each of the at least one heterojunction structure includes a channel layer and a barrier layer, the epitaxial structure includes a gate region, and in each of the at least one heterojunction structure, a part of the barrier layer corresponding to the gate region is removed to form a hole; a gate electrode on the gate region, where the gate electrode fills the hole, and surrounds the channel layer; and a source electrode and a drain electrode respectively at two sides of the gate electrode.

### CROSS REFERENCE TO RELATED APPLICATIONS

This application claims priority to Chinese Patent Application No. 2022113702967 filed on Nov. 3, 2022, the entire content of which is incorporated herein by reference.

### TECHNICAL FIELD

The present disclosure relates to the technical field of semiconductor, in particular to semiconductor structures and manufacturing methods therefor.

### BACKGROUND

Gallium nitride (GaN), as a representative of the third generation of wide band gap semiconductor, is attracting widespread attention. Properties of GaN mainly include high electron mobility and high two-dimensional electron gas (2DEG) concentration. In addition, GaN material has stable chemical properties, high temperature resistance and corrosion resistance, and has inherent advantages in high-frequency, high-power, and radiation-resistant applications.

In a planar device, current laterally flows in a quantum well formed by a heterojunction structure. Under a reverse bias, a distribution of electric field in a device is usually uneven. Generally, severe electric field concentration occurs at an edge of the gate electrode or the drain electrode, and the electric field there increases rapidly with an increase of reverse voltage. When a critical breakdown field strength is reached, the device is broken down.

A high breakdown voltage means that the device operates in a larger voltage range, can achieve higher power density, and has higher reliability. Therefore, how to improve the breakdown voltage of a device is a key concern for electronic device researchers.

### SUMMARY

According to the first aspect of the present disclosure, a semiconductor structure is provided, including:
a substrate structure;
an epitaxial structure on the substrate structure, where the epitaxial structure includes at least one heterojunction structure sequentially stacked in a direction away from the substrate structure;
each of the at least one heterojunction structure includes a channel layer and a barrier layer;
the epitaxial structure includes a gate region;
in each of the at least one heterojunction structure, a part of the barrier layer corresponding to the gate region is removed to form a hole;
a gate electrode on the gate region, where the gate electrode fills up the hole, and surrounds the channel layer; and
a source electrode and a drain electrode respectively at two sides of the gate electrode.

In some embodiments, the hole penetrates through the barrier layer in a direction parallel to the substrate structure; or the hole partially penetrates the barrier layer in a direction parallel to the substrate structure.

In some embodiments, a side of the hole close to the channel layer is at the barrier layer, an interface of the barrier layer and the channel layer, or the channel layer.

In some embodiments, materials of the channel layer and the barrier layer include group III nitride materials, and surfaces of the channel layer and the barrier layer far from the substrate structure are N-face polarities.

In some embodiments, there are a plurality of the epitaxial structures formed on the substrate structure, and the plurality of epitaxial structures are parallel and spaced.

In some embodiments, a plurality of the source electrodes for the plurality of epitaxial structures are electrically connected or separated from each other; and/or
a plurality of the source electrodes for the plurality of epitaxial structures are electrically connected or separated from each other; and/or
a plurality of the drain electrodes for the plurality of epitaxial structures are electrically connected or separated from each other.

In some embodiments, the substrate structure includes silicon on insulator, silicon, sapphire, or silicon carbide.

In some embodiments, the substrate structure includes a base and a dielectric layer on the base, and the epitaxial structure is bonded to the dielectric layer.

In some embodiments, the channel layer and/or barrier layer include an N-type doped layer or a P-type doped layer.

In some embodiments, the source electrode and the drain electrode are at a top of the epitaxial structure; or
the source electrode and drain electrode are in an arched structure, on a top and sides of the epitaxial structure.

In some embodiments, the semiconductor structure further includes an N-type heavily doped layer on both sides of the epitaxial structure, where the N-type heavily doped layer is on a top and sides of the epitaxial structure, and the source electrode and/or the drain electrode are electrically connected to the epitaxial structure through the N-type heavily doped layer.

In some embodiments, the semiconductor structure further includes a gate insulating layer between the channel layer surrounded by the gate electrode and the gate electrode.

In some embodiments, the semiconductor structure further includes a protecting layer, where the protecting layer covers the epitaxial structure.

In some embodiments, the at least one heterojunction structure is a nanowire structure or a nanosheet structure.

According to the second aspect of the present disclosure, a manufacturing method for a semiconductor structure is provided, including:
providing a substrate structure;
forming an epitaxial structure on the substrate structure, where the epitaxial structure includes at least one heterojunction structure sequentially stacked in a direction away from the substrate structure; each of the at least one heterojunction structure includes a channel layer and a barrier layer;
the epitaxial structure includes a gate region; and a hole is formed at a part of the barrier layer corresponding to the gate region;
forming a gate electrode on the gate region, where the gate electrode fills the hole, and surrounds the channel layer; and
forming a source electrode and a drain electrode respectively at two sides of the gate electrode.

In some embodiments, forming the epitaxial structure on the substrate structure includes:
forming the epitaxial structure on a growth base;
bonding the epitaxial structure to the substrate structure; and removing the growth base.

In some embodiments, before bonding the epitaxial structure to the substrate structure, or after bonding the epitaxial structure to the substrate structure, the manufacturing method further includes: patterning the epitaxial structure to form a plurality of the epitaxial structures that are spaced.

In some embodiments, forming the hole at the part of the barrier layer corresponding to the gate region includes:
forming a protecting layer covering the epitaxial structure;
removing the protecting layer on a sidewall of the barrier layer in the gate region; and
etching the barrier layer at the gate region by using the protecting layer as a mask, to form the hole.

In some embodiments, the source electrode and the drain electrode are at a top of the epitaxial structure; or
the source electrode and drain electrode are in an arched structure, on a top and sides of the epitaxial structure.

In some embodiments, the hole penetrates through the barrier layer in a direction parallel to the substrate structure; or the hole partially penetrates the barrier layer in a direction parallel to the substrate structure.

### BRIEF DESCRIPTION OF DRAWINGS

FIG. 1 is a schematic diagram of a semiconductor structure after a hole is formed according to embodiment 1 of the present disclosure.

FIG. 2 is a schematic diagram of a semiconductor structure after a gate electrode is formed according to embodiment 1 of the present disclosure.

FIG. 3a is a cross-sectional schematic diagram of the semiconductor structure shown in FIG. 2.

FIG. 3b is another cross-sectional schematic diagram of the semiconductor structure shown in FIG. 2.

FIG. 4 is a schematic diagram of a semiconductor structure with a protecting layer according to embodiment 1 of the present disclosure.

FIG. 5 is a cross-sectional schematic diagram of a semiconductor structure with a gate insulating layer according to embodiment 1 of the present disclosure.

FIGS. 6 and 7 are schematic diagrams of semiconductor structures according to embodiment 2 of the present disclosure.

FIGS. 8 to 10 are schematic diagrams of semiconductor structures according to embodiment 3 of the present disclosure.

Explanation of reference numerals: substrate structure 1, heterojunction structure 2, channel layer 201, barrier layer 202, hole 3, gate electrode 4, source electrode 5, drain electrode 6, N-type heavily doped layer 7, gate insulating layer 8, protecting layer 9, epitaxial structure 100.

### DETAILED DESCRIPTION

Exemplary embodiments will be described in detail herein, examples of which are illustrated in the accompanying drawings. Where the following description refers to the drawings, elements with the same numerals in different drawings refer to the same or similar elements unless otherwise indicated. Embodiments described in the following embodiments do not represent all embodiments consistent with the present disclosure. On the contrary, they are examples of a structure consistent with some aspects of the present disclosure described in detail in the appended claims.

The purpose of the present disclosure is to provide semiconductor structures and manufacturing methods therefor to improve the breakdown voltage.

### Embodiment 1

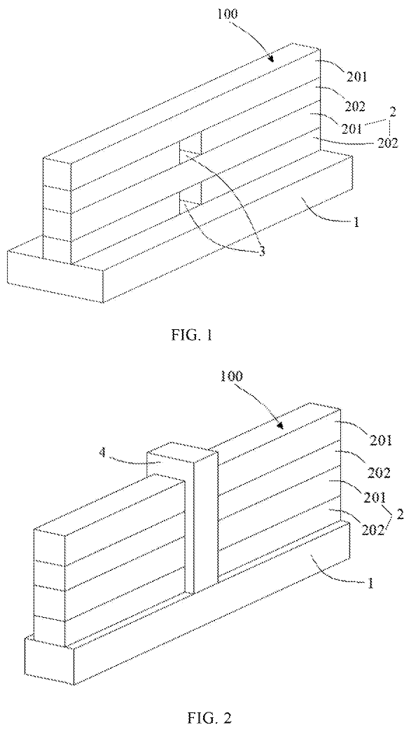

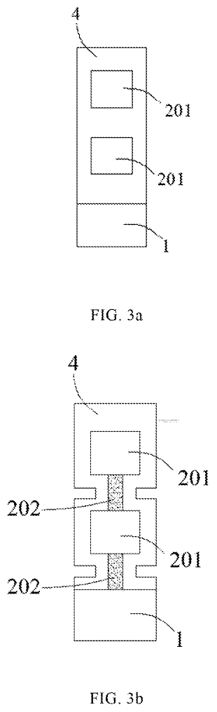

Embodiment 1 of the present disclosure provides a semiconductor structure and a manufacturing method for a semiconductor structure. FIG. 1 is a schematic diagram of a semiconductor structure after a hole 3 is formed according to embodiment 1 of the present disclosure. FIG. 2 is a schematic diagram of a semiconductor structure after a gate electrode 4 is formed according to embodiment 1 of the present disclosure. FIGS. 3a and 3b are cross-sectional schematic diagrams of the semiconductor structure shown in FIG. 2. FIG. 5 is a cross-sectional schematic diagram of a semiconductor structure with a gate insulating layer according to embodiment 1 of the present disclosure. The manufacturing method of the semiconductor structure can include steps 100-130.

In step 100, a substrate structure 1 is provided.

In step 110, an epitaxial structure 100 is formed on the substrate structure 1, where the epitaxial structure 100 includes at least one heterojunction structure 2 sequentially stacked in a direction away from the substrate structure 1; each of the at least one heterojunction structure 2 includes a channel layer 201 and a barrier layer 202, where the barrier layer 202 is located on a side of the channel layer 201 facing the substrate structure 1. In some embodiments, for each heterojunction structure 2, the channel layer 201 is located on a side of the barrier layer 202 facing the substrate structure 1.

In step 120, the epitaxial structure 100 includes a gate region; and a hole 3 is formed at a part of the barrier layer 202 corresponding to the gate region.

In step 130, a gate electrode is formed on the gate region, where the gate electrode fills the hole, and surrounds the channel layer.

In step 140, a source electrode 5 and a drain electrode 6 are respectively formed at two sides of the gate electrode 4.

For the semiconductor structure in the embodiment of the present disclosure, the gate electrode 4 surrounds the heterojunction structure 2 in all directions through the hole 3 provided in the barrier layer 202 of the heterojunction structure 2, which greatly improves an ability of the gate electrode 4 to control carriers in the heterojunction structure 2, and therefore, significantly increases the breakdown voltage of the semiconductor structure, reduces a leakage problem, and improves the efficiency and linearity of the semiconductor structure.

In some embodiments, the heterojunction structure 2 is formed into a nanowire or nanosheet structure, the heterojunction structure 2 is confined, and the two-dimensional electron gas or hole gas carriers within the heterojunction structure 2 exhibit an approximate one-dimensional transport pattern during the migration process, which can improve the carrier mobility.

The following is a detailed explanation of the steps of the manufacturing method for the semiconductor structure according to the embodiments of the present disclosure.

In step 100, a substrate structure 1 is provided.

The substrate structure 1 can include a silicon substrate, a silicon carbide substrate, a sapphire substrate, or silicon on insulator, which is not limited in the present disclosure. The silicon on insulator can include a back substrate, a buried oxygen layer, and a silicon top layer that are stacked. The back substrate can be (100) type monocrystalline silicon, and the silicon top layer can be (111) type monocrystalline silicon. The buried oxygen layer is located between the back substrate and the silicon top layer, and a material of the buried oxygen layer can be an insulating material, such as SiO2. In some embodiments, the substrate structure 1 can also be a composite structure including a base and a dielectric layer formed on the base. The epitaxial structure 100 is bonded to the dielectric layer, where the base can be a conventional base such as silicon, silicon carbide, or sapphire, and the dielectric layer can be an oxide material such as SiO2 or Al2O3.

In step 110, an epitaxial structure 100 is formed on the substrate structure 1, where the epitaxial structure 100 includes at least one heterojunction structure 2 sequentially stacked in a direction away from the substrate structure 1; each of the at least one heterojunction structure 2 includes a channel layer 201 and a barrier layer 202, where the barrier layer 202 is located on a side of the channel layer 201 facing the substrate structure 1.

The epitaxial structure 100 can include multiple heterojunction structures 2, and multiple heterojunction structures 2 are stacked on the substrate structure 1, which provides multiple carrier migration channels, thereby further improving the carrier migration rate. The heterojunction structure 2 includes a channel layer 201 and a barrier layer 202. The barrier layer 202 is located on a side of the channel layer 201 facing the substrate structure 1. The materials of the channel layer 201 and barrier layer 202 include III-V compound materials, and further, the materials of the channel layer 201 and barrier layer 202 include III-V nitride materials. In some embodiments, the surfaces of the channel layer 201 and barrier layer 202 far from the substrate structure 1 have N-face polarities. For example, the materials of the channel layer 201 and barrier layer 202 include at least one of GaN, AlGaN, InGaN, or AlInGaN. A bandgap width of the barrier layer 202 can be greater than a bandgap width of the channel layer 201. In some embodiments, ions are doped into the heterojunction structure 2, with the doping ions being N-type or P-type. The channel layer 201 and/or barrier layer 202 are N-type doped layer or P-type doped layer. When the channel layer 201 and/or barrier layer 202 are N-type doped layer, the doping ions can be Si. When the channel layer 201 and/or barrier layer 202 are P-type doped layer, the doping ions can be Mg. The present disclosure does not impose limitations on this. In addition, an orthographic projection of the epitaxial structure 100 on the substrate structure 1 can be in a strip shape. The barrier layer 202 can include an N-type doped layer or a P-type doped layer, reducing the conduction resistance of the semiconductor structure and improving surface characteristics. The channel layer 201 can include an N-type doped layer or a P-type doped layer, which is used to adjust an energy band structure of the semiconductor structure, to avoid carrier accumulation, and adjust an electron concentration in the channel layer 201 below the gate electrode.

For example, forming the epitaxial structure 100 on the substrate structure 1 can include: forming the epitaxial structure 100 on a growth base; and bonding the epitaxial structure 100 to substrate structure 1 and remove the growth base. In the manufacturing method for a semiconductor structure in the present disclosure, an epitaxial structure is first formed on a growth base, and then transferred and bonded on the substrate structure 1, and the substrate structure 1 has an auxiliary circuit system, which reduces the process flow, reduces device volume, and saves costs.

In step 120, the epitaxial structure 100 includes a gate region; and a hole 3 is formed at a part of the barrier layer 202 corresponding to the gate region.

Taking the epitaxial structure 100 including multiple heterojunction structures 2 as an example, a hole 3 is formed at a part of the barrier layer 202 of each heterojunction structure 2 corresponds to the gate region. As shown in FIG. 3a, the hole 3 can penetrate the barrier layer 202 in a direction parallel to the substrate structure 1, which means that the hole 3 can be a through hole, such as a rectangular hole, a square hole, a circular hole, an elliptical hole, a trapezoidal hole, etc. In other embodiments, as shown in FIG. 3b, the hole 3 partially penetrates the barrier layer 202 in a direction parallel to the substrate structure 1. A central axis of the hole 3 can be parallel to the width direction of the epitaxial structure 100. In a direction perpendicular to the substrate structure 1, the length of the hole 3 can be equal to the height of the barrier layer 202, or the length of the hole 3 can also be smaller than the height of the barrier layer 202. In addition, a side of the hole 3 close to the channel layer 201 is located at the barrier layer 202, the interface between the barrier layer 202 and the channel layer 201, or the channel layer 201. In the present disclosure, a side close to the channel layer 201 of the hole 3 that horizontally penetrates through the barrier layer 202 can stop at the interface, or further stop at the channel layer 201 through etching, causing the electronic channel between the source electrode and the drain electrode of the semiconductor structure to be interrupted. Therefore, a switching device can be effectively turned off under zero gate bias voltage.

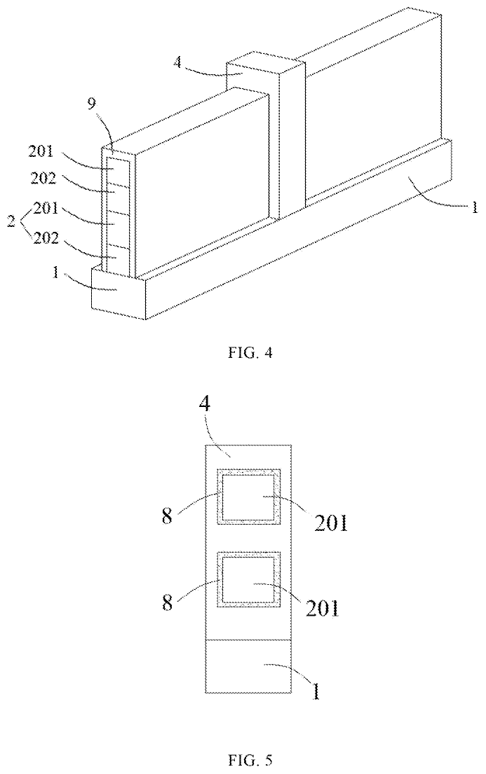

For example, forming the hole 3 at the part of the barrier layer 202 corresponding to the gate region includes: forming a protecting layer 9 (see FIG. 4) covering the epitaxial structure 100; removing the protecting layer 9 on a sidewall of the barrier layer 202 in the gate region; etching the barrier layer 202 at the gate region by using the protecting layer 9 as a mask, to form the hole 3; and forming a gate electrode 4 on the gate region, where the gate electrode 4 fills the hole 3, and surrounds the channel layer 201, i.e., the channel layer 201 is covered. A material of the protecting layer 9 can be silicon dioxide or the like.

For example, the epitaxial structure 100 includes multiple heterojunction structures 2, and the barrier layer 202 of each heterojunction structure 2 is provided with a hole 3, and the gate electrode 4 fills each hole 3. The gate electrode 4 can be formed by physical vapor deposition or chemical vapor deposition. There is a gate insulating layer 8 (see FIG. 5) between the channel layer 201 surrounded by the gate electrode 4 and the gate electrode 4, which can reduce the gate leakage current. The gate insulating layer 8 can be formed by the protecting layer 9 mentioned above.

The semiconductor structure according to embodiment 1 of the present disclosure can include:
a substrate structure 1;
an epitaxial structure 100 on the substrate structure1, where the epitaxial structure 100 includes at least one heterojunction structure 2 sequentially stacked in a direction away from the substrate structure 1;
each of the at least one heterojunction structure 2 includes a channel layer 201 and a barrier layer 202, and the barrier layer 202 is located on the side of the channel layer 201 facing the substrate structure 1;
the epitaxial structure 100 includes a gate region; in each of the at least one heterojunction structure 2, a part of the barrier layer 202 corresponding to the gate region is provided with a hole 3;
a gate electrode 4 on the gate region, where the gate electrode 4 fills the hole 3, and surrounds the channel layer 201.

The manufacturing method of the semiconductor structure provided in Example 1 belongs to the same inventive concept as the semiconductor structure, and descriptions of relevant details and beneficial effects can refer to each other, and will not be repeated here.

### Embodiment 2

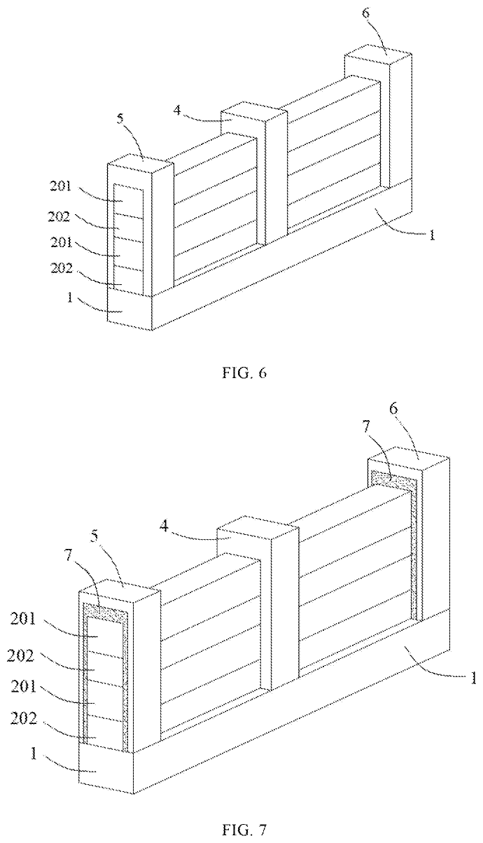

FIGS. 6 and 7 are schematic diagrams of semiconductor structures according to embodiment 2 of the present disclosure. A manufacturing method of a semiconductor structure and a semiconductor structure according to embodiment 2 of the present disclosure is roughly the same as that according to embodiment 1 of the present disclosure, except that the semiconductor structure further includes a source electrode 5 and a drain electrode 6. The source electrode 5 and the drain electrode 6 are respectively arranged on both sides of the gate electrode 4. In an extension direction of the epitaxial structure 100, the source electrode 5 and the drain electrode 6 are respectively arranged on both sides of the gate electrode 4. The extension direction of the epitaxial structure 100 can be a extension direction of the orthogonal projection of the epitaxial structure 100 on the substrate structure 1. The source electrode 5 and drain electrode 6 are located at the top of the epitaxial structure 100. In other embodiments of the present disclosure, the source electrode 5 and drain electrode 6 are in an arched structure, and cover the top and sides of the epitaxial structure 100. In some embodiments, the source electrode 5 and/or drain electrode 6 are in ohmic contact with the sidewall of the epitaxial structure 100.

In other embodiments, as shown in FIG. 7, the semiconductor structure further includes an N-type heavily doped layer 7. The N-type heavily doped layer 7 is located on both sides of the epitaxial structure 100, and the N-type heavily doped layer 7 covers the top and sides of the epitaxial structure 100. The source electrode 5 and/or drain electrode 6 are electrically connected to the epitaxial structure 100 through the N-type heavily doped layer 7. The N-type heavily doped layer 7 can directly form an ohmic contact layer between the source electrode 5 and/or drain electrode 6 and the epitaxial structure 100 without high-temperature annealing, which can avoid decreases of performance of the heterojunction structure 2 and electron migration rate caused by high temperature during the annealing process.

The N-type heavily doped layer 7 can be formed on the epitaxial structure 100 through secondary epitaxy. Before the formation of the source electrode 5 and the drain electrode 6 on both sides of the gate electrode 4, the N-type heavily doped layer 7 can be secondary epitaxed on both ends of the epitaxial structure 100. The source electrode 5 and drain electrode 6 are prepared on the N-type heavily doped layer 7, and the source electrode 5 and drain electrode 6 are electrically connected to the epitaxial structure 100 through the N-type heavily doped layer 7. In the N-type heavily doped layer 7, the N-type doped ions can include at least one of Si ions, Ge ions, Sn ions, Se ions, or Te ions. For different N-type doped ions, the doping concentration can be greater than 1E18/cm3. The N-type heavily doped layer 7 can include a group III nitride based material, such as GaN, AlN, InN, AlGaN, InGaN, AlInN, or AlInGaN.

### Embodiment 3

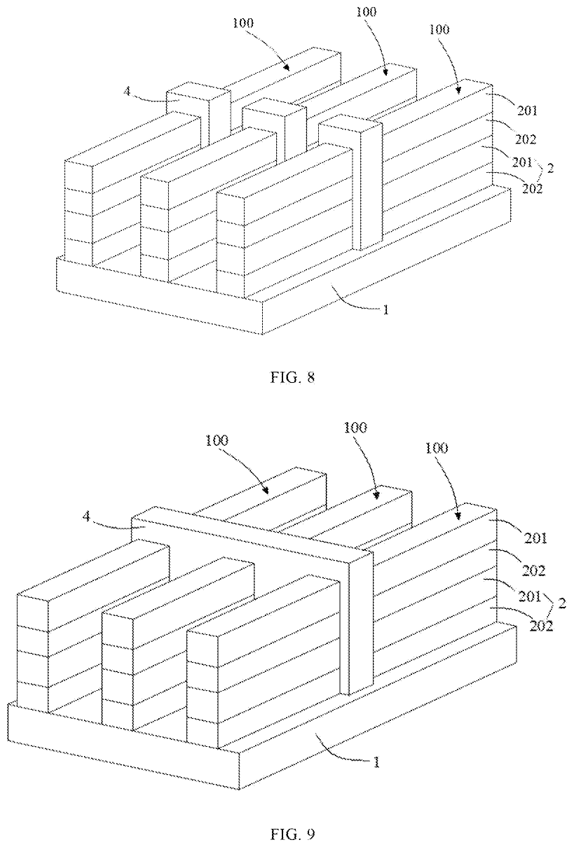

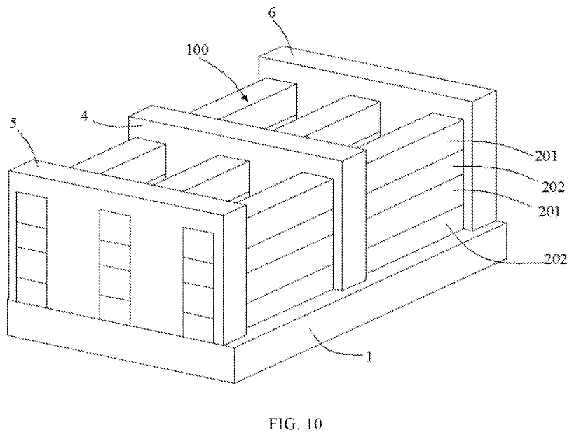

FIGS. 8 to 10 are schematic diagrams of semiconductor structures according to embodiment 3 of the present disclosure. A manufacturing method of a semiconductor structure and a semiconductor structure in embodiment 3 of the present disclosure is roughly the same as that in embodiment 1 or embodiment 2 of the present disclosure. The difference is that there are a plurality of the epitaxial structures 100, and the plurality of epitaxial structures 100 are parallel and spaced. which is equivalent to providing multiple carrier migration channels and can further improve the carrier migration rate. The epitaxial structures 100 can be spaced along a direction perpendicular to the extension direction of the epitaxial structure 100. As shown in FIG. 9, multiple gate electrodes 4 corresponding to multiple epitaxial structures 100 are electrically connected together. As shown in FIG. 10, multiple source electrodes 5 corresponding to multiple epitaxial structures 100 are electrically connected together, and multiple drain electrodes 6 corresponding to multiple epitaxial structures 100 are electrically connected together. In other embodiment, multiple gate electrodes 4 corresponding to multiple epitaxial structures 100 are separated from each other, multiple source electrodes 5 corresponding to multiple epitaxial structures 100 are separated from each other, and multiple drain electrodes 6 corresponding to multiple epitaxial structures 100 are separated from each other, which can meet different performance usage requirements.

In the present disclosure, there can be a plurality of the epitaxial structures 100 that are parallel and spaced, and the epitaxial structures 100 including heterojunction structures are connected between the source electrode and the drain electrode, which improves the breakdown voltage and dynamic characteristic. The plurality of epitaxial structures 100 increase the gate control area, which enhances gate control capability, increases carrier density, maintains stable semiconductor mobility, reduces surface resistance, and greatly improves the frequency characteristic of the device.

The formation of multiple epitaxial structures 100 on substrate structure 1 can include patterning the epitaxial structure 100 formed in embodiment 1 to form multiple spaced epitaxial structures 100. The patterning step can occur before or after bonding the epitaxial structure 100 to the substrate structure 1. The present disclosure can pattern the epitaxial structure 100 through a photolithography process.

In some embodiments, for the semiconductor structures and manufacturing methods therefor in the present disclosure, the gate electrode surrounds the channel layer at the gate region of the heterojunction structure in all directions through the hole provided in the barrier layer of the heterojunction structure. Because the barrier layer is penetrated to form the hole, the semiconductor structure can be effectively turned off under zero gate bias voltage, forming an enhanced device. On the other hand, through the hole, an omnidirectional surround gate electrode can be manufactured, which greatly improves an ability of the gate electrode to control carriers in the heterojunction structure, and therefore, significantly increases the breakdown voltage of the semiconductor structure, reduces a leakage problem, and improves the efficiency and linearity of the semiconductor structure.

In some embodiments, in the present disclosure, there can be a plurality of the epitaxial structures that are parallel and spaced, and the epitaxial structures including heterojunction structures are connected between the source electrode and the drain electrode, which improves the breakdown voltage and dynamic characteristic. The plurality of epitaxial structures increase the gate control area, which enhances gate control capability, increases carrier density, maintains stable semiconductor mobility, reduces surface resistance, and greatly improves the frequency characteristic of the device.

In some embodiments, in the present disclosure, a side close to the channel layer of the hole that horizontally penetrates through the barrier layer can stop at the interface, or further stop at the channel layer through etching, causing the electronic channel between the source electrode and the drain electrode of the semiconductor structure to be interrupted. Therefore, a switching device can be effectively turned off under zero gate bias voltage.

In some embodiments, in the semiconductor structure of the present disclosure, the barrier layer can include an N-type doped layer or a P-type doped layer, reducing the conduction resistance of the semiconductor structure and improving surface characteristics. The channel layer can include an N-type doped layer or a P-type doped layer, which is used to adjust an energy band structure of the semiconductor structure, to avoid carrier accumulation, and adjust an electron concentration in the channel layer below the gate electrode.

In some embodiments, in the manufacturing method for a semiconductor structure in the present disclosure, an epitaxial structure is first formed on a growth base, and then transferred and bonded on the substrate structure, and the substrate structure has an auxiliary circuit system, which reduces the process flow, reduces device volume, and saves costs.

The above are only some preferred embodiments of the present disclosure, and do not limit the present disclosure in any form. Although the present disclosure has been disclosed as above in the preferred embodiments, the preferred embodiments are not used to limit the present disclosure. Any skilled person familiar with this profession, without departing from the scope of the technical solutions of the present disclosure, may use the technical content disclosed above to change or modify them into equivalent embodiments with equivalent changes. However, any simple modifications, equivalent changes and modifications made to the above embodiments based on the technical essence of the present disclosure, which do not deviate from the content of the technical solution of the present disclosure, still fall within the scope of the technical solution of the present disclosure.

What is claimed is:

1. A semiconductor structure, comprising:
a substrate structure;
an epitaxial structure on the substrate structure, wherein the epitaxial structure comprises at least one heterojunction structure sequentially stacked in a direction away from the substrate structure; each of the at least one heterojunction structure comprises a channel layer and a barrier layer; the epitaxial structure comprises a gate region; and in each of the at least one heterojunction structure, a part of the barrier layer corresponding to the gate region is removed to form a hole;
a gate electrode on the gate region, wherein the gate electrode fills up the hole, and surrounds the channel layer; and
a source electrode and a drain electrode respectively at two sides of the gate electrode.

2. The semiconductor structure according to claim 1, wherein the hole penetrates through the barrier layer in a direction parallel to the substrate structure; or the hole partially penetrates the barrier layer in a direction parallel to the substrate structure.

3. The semiconductor structure according to claim 1, wherein a side of the hole close to the channel layer is at the barrier layer, an interface of the barrier layer and the channel layer, or the channel layer.

4. The semiconductor structure according to claim 1, wherein materials of the channel layer and the barrier layer comprise group III nitride materials, and surfaces of the channel layer and the barrier layer far from the substrate structure are N-face polarities.

5. The semiconductor structure according to claim 1, wherein there are a plurality of the epitaxial structures formed on the substrate structure, and the plurality of epitaxial structures are parallel and spaced.

6. The semiconductor structure according to claim 5, wherein
a plurality of the gate electrodes for the plurality of epitaxial structures are electrically connected or separated from each other; and/or
a plurality of the source electrodes for the plurality of epitaxial structures are electrically connected or separated from each other; and/or
a plurality of the drain electrodes for the plurality of epitaxial structures are electrically connected or separated from each other.

7. The semiconductor structure according to claim 1, wherein the substrate structure comprises silicon on insulator, silicon, sapphire, or silicon carbide.

8. The semiconductor structure according to claim 1, wherein the substrate structure comprises a base and a dielectric layer on the base, and the epitaxial structure is bonded to the dielectric layer.

9. The semiconductor structure according to claim 1, wherein the channel layer and/or barrier layer comprise an N-type doped layer or a P-type doped layer.

10. The semiconductor structure according to claim 1, wherein
the source electrode and the drain electrode are at a top of the epitaxial structure; or
the source electrode and drain electrode are in an arched structure, on a top and sides of the epitaxial structure.

11. The semiconductor structure according to claim 1, further comprising an N-type heavily doped layer on both sides of the epitaxial structure, wherein the N-type heavily doped layer is on a top and sides of the epitaxial structure, and the source electrode and/or the drain electrode are electrically connected to the epitaxial structure through the N-type heavily doped layer.

12. The semiconductor structure according to claim 1, further comprising a gate insulating layer between the channel layer surrounded by the gate electrode and the gate electrode.

13. The semiconductor structure according to claim 1, further comprising a protecting layer on the epitaxial structure.

14. The semiconductor structure according to claim 1, wherein the at least one heterojunction structure is a nanowire structure or a nanosheet structure.

15. A manufacturing method for a semiconductor structure, comprising:
providing a substrate structure;
forming an epitaxial structure on the substrate structure, wherein the epitaxial structure comprises at least one heterojunction structure sequentially stacked in a direction away from the substrate structure; each of the at least one heterojunction structure comprises a channel layer and a barrier layer; and the epitaxial structure comprises a gate region; and a hole is formed at a part of the barrier layer corresponding to the gate region;
forming a gate electrode on the gate region, wherein the gate electrode fills the hole, and surrounds the channel layer; and
forming a source electrode and a drain electrode respectively at two sides of the gate electrode.

16. The manufacturing method according to claim 15, wherein forming the epitaxial structure on the substrate structure comprises:
forming the epitaxial structure on a growth base;
bonding the epitaxial structure to the substrate structure; and removing the growth base.

17. The manufacturing method according to claim 16, wherein before bonding the epitaxial structure to the substrate structure, or after bonding the epitaxial structure to the substrate structure, the manufacturing method further comprises:
patterning the epitaxial structure to form a plurality of the epitaxial structures that are spaced.

18. The manufacturing method according to claim 15, wherein forming the hole at the part of the barrier layer corresponding to the gate region comprises:
forming a protecting layer covering the epitaxial structure;
removing the protecting layer on a sidewall of the barrier layer in the gate region; and
etching the barrier layer at the gate region by using the protecting layer as a mask, to form the hole.

19. The manufacturing method according to claim 15, wherein
the source electrode and the drain electrode are at a top of the epitaxial structure; or
the source electrode and drain electrode are in an arched structure, on a top and sides of the epitaxial structure.

20. The manufacturing method according to claim 15, wherein the hole penetrates through the barrier layer in a direction parallel to the substrate structure; or the hole partially penetrates the barrier layer in a direction parallel to the substrate structure.
